(19) United States
(12) Patent Application Publication
(10) Pub. No.: US 2023/0369543 A1
(43) Pub. Date: Nov. 16, 2023

(54) MICRO LIGHT-EMITTING COMPONENT, DISPLAY DEVICE AND MANUFACTURING METHOD THEREOF

(71) Applicant: Xiamen San'an Optoelectronics Co., Ltd., Fujian (CN)

(72) Inventors: Zheng WU, Fujian (CN); Zhiyuan WANG, Fujian (CN); Zhilei QIN, Fujian (CN); Chiaen LEE, Fujian (CN)

(73) Assignee: Xiamen San'an Optoelectronics Co., Ltd., Fujian (CN)

(21) Appl. No.: 18/166,468

(22) Filed: Feb. 8, 2023

(30) Foreign Application Priority Data
May 13, 2022 (CN) 202210521348.X

(51) Int. Cl. H01L 33/48; H01L 33/00

(52) U.S. Cl. CPC H01L 33/483; H01L 33/0075; H01L 33/0093; H01L 33/32

(57) ABSTRACT

The disclosure relates to a micro light-emitting component, a display device and a manufacturing method thereof, including: at least one support structure, the support structure is composed of a dielectric layer and/or a semiconductor layer to form a bridge arm structure; a semiconductor layer sequence; the semiconductor layer sequence is directly or indirectly in contact and fixed with the substrate through the bridge arm, and the support structure further includes a protrusion extending from the substrate toward the support structure, and a distance between the protrusion and the support structure is 0 µm to 1 µm, thereby improving the transfer yield of the micro light-emitting component.

### CROSS-REFERENCE TO RELATED APPLICATION

This application claims the priority benefit of China application serial no. 202210521348.X, filed on May 13, 2022. The entirety of the above-mentioned patent application is hereby incorporated by reference herein and made a part of this specification.

### BACKGROUND

### Technical Field

The present disclosure relates to a semiconductor structure, in particular to a micro light-emitting component, a display device and a manufacturing method thereof.

### Description of Related Art

At present, transferring micro-LEDs is performed mainly by utilizing van der Waals force, electrostatic force or magnetic force, and so on to transfer the micro-LEDs on a carrier substrate to a receiving substrate. Generally speaking, the micro-LEDs are held by a support structure, so that the micro-LEDs can be easily picked up from the carrier substrate, transported and transferred to the receiving substrate for placement, and the quality of the micro-LEDs secured by the support structure will not be affected by other internal or external factors during transfer.

Currently, photosensitive materials or single-layer dielectric films are adopted to fabricate a fixing structure. However, since the size of the micro-LEDs is designed to be smaller, which brings limitation to the width of the fixing structure, and therefore the structural strength of the fixing structure becomes fragile. In the chip manufacturing process, in order to improve the transfer yield, a suspended structure of the micro-LED is developed. How to make the support structure temporarily hold the micro-LED and how to avoid holding problems during transportation without increasing difficulty of imprinting transfer in subsequent transfer of the board have become the technical problems in the current industry.

### SUMMARY

In order to solve the problems encountered in the related art, the present disclosure provides a micro light-emitting component, a display device and a manufacturing method thereof, so as to achieve the transfer yield when the board is transferred and the bridge arm strength when the sacrificial layer is taken into account.

A micro light-emitting component includes: a substrate, a main body with a semiconductor layer sequence, and a support structure. The support structure fixes the main body on the substrate, and a cavity is between the main body and the upper surface of the substrate. The support structure includes a protrusion pointing at the support structure from below the support structure. The protrusion has at least one end portion, the distance between the end portion and the support structure is 0 µm to 1 µm, preferably 0 µm in some cases, i.e., the end portion is directly in contact with the support structure, and the end portion provides supporting force to the support structure.

In the present disclosure, preferably, the support structure at least includes a first dielectric layer and/or a second dielectric layer. The material of the first dielectric layer includes silicon oxide, and the material of the second dielectric layer includes silicon nitride. The support structure at least includes a first dielectric layer and a second dielectric layer. The material of the first dielectric layer is different from the material of the second dielectric layer. The first dielectric layer is located between the second dielectric layer and the semiconductor layer sequence, and the second dielectric layer is configured to connect the support structure and the main body. The first dielectric layer is located on the surface of the second dielectric layer. A cavity is between the main body and the upper surface of the substrate. The thickness of the second dielectric layer is greater than the thickness of the first dielectric layer. The thickness of the second dielectric layer is 1.5 times to 10 times the thickness of the first dielectric layer. The second dielectric layer is located on the main body, and the first dielectric layer at least partially covers the outer surface of the second dielectric layer. In order to provide sufficient support, a thin first dielectric layer is adopted mainly to eliminate the stress in the process and to avoid rupture of the support structure caused by stress release during the bonding process. The second dielectric layer is mainly configured to provide a bridge between the chip and the substrate during transfer. The thickness of the second dielectric layer is significantly greater than the thickness of the first dielectric layer. In the meantime, the difficulty of stress regulation of the support structure is reduced by utilizing the difference in material and film-forming stress between the two dielectric layers. The first dielectric layer is located on the main body, and the second dielectric layer at least partially covers the inner surface of the first dielectric layer.

According to the present disclosure, preferably, the first dielectric layer at least includes the material of the negative stress direction, and the material of the second dielectric layer at least includes the material of the positive stress direction. For example, the first dielectric layer is made of silicon oxide with a thin thickness. The film-forming stress of silicon oxide is greater than that of silicon nitride in the process, and therefore silicon oxide may be used to adjust the stress. However, it is not advisable to set the thickness of silicon oxide too thick. Then, a second dielectric layer using thicker silicon nitride is fabricated, and the film-forming quality of the second dielectric layer is improved.

According to the present disclosure, preferably, the material of the first dielectric layer is silicon oxide, and the first dielectric layer is connected to the semiconductor layer sequence of the main body. The material of the second dielectric layer is silicon nitride, and the thickness of the first dielectric layer is 0.1 µm to 0.5 µm. The thickness of the second dielectric layer is 0.15 µm to 0.3 µm, 0.3 µm to 0.8 µm, or 0.8 µm to 2 µm, and the widths of the first dielectric layer and the second dielectric layer are 1 µm to 20 µm. Through the design of thicknesses and widths, the overall structural stability is improved.

According to the present disclosure, preferably, the first dielectric layer at least includes the material of the negative stress direction, and the material of the second dielectric layer at least includes the material of the positive stress direction, different stress directions are utilized to regulate and control the growth stress of the support structure.

According to the present disclosure, the protrusion is ridge-shaped or pointed. The width of the end portion is not greater than the width of other regions of the protrusion, so the overall reliability of the support structure is improved. The protrusion extends from a fixing anchor toward the bridge arm, and the protrusion includes a dielectric material, adhesive material or metal. For example, the protrusion includes epoxy resin, polyimide, benzocyclobutene, or silicone. Preferably, the elastic modulus of the material of the protrusion is 0.5 to 2 GPa, for example, the elastic modulus of silica gel is about 1.2 GPa, and the Poisson’s ratio is 0.48. The silicone material is relatively more elastic after molding, while serving as a protrusion, it is possible to avoid debris caused by crushing, and also improve the reliability of the device and enhance the shock resistance of the component without affecting the pickup in subsequent process.

According to the present disclosure, preferably, the support structure has a suspended portion whose surface is completely exposed or the upper surface is exposed. The protrusion extends from the substrate toward the suspended portion of the support structure, and the angle between the suspended portion and the horizontal plane is -10° to 10°. The distance between the suspended portion and the side wall of the main body is 0 µm to 10 µm, so as to avoid excessive bending of the support structure, which might cause the main body to contact the surface of the adhesive layer at the bottom of the cavity during the lamination and imprinting process, resulting in a decrease in yield.

According to the present disclosure, preferably, the support structure includes a bridge arm, the thickness of the bridge arm is 0.2 µm to 1 µm, and the distance between the end portion and the support structure is 0 µm. The protrusion provides a supporting force to the support structure. Or, the thickness of the bridge arm is 1 µm to 2 µm, and the width of the end portion is 0.1 µm to 0.5 µm. In this manner, a mechanical concentration is formed at the end portion. During the transfer of the lamination imprint, the mechanical concentration helps to support breakage of the support structure.

According to the present disclosure, preferably, the semiconductor layer sequence is the main body, the angle between the side wall of the main body and the horizontal plane is 70° to 100°, and the distance between the end portion and the side wall is 0.5 µm to 1 µm. By using the angle between the side wall and the horizontal plane, the formation of the protrusion is controlled, so that the manufacturing process is simplified, and the production cost is reduced.

According to the present disclosure, preferably, the angle between the protrusion and the horizontal plane is 45° to 75°, the inclined angle makes implementation easier, and the protrusion has less resistance during transfer, so that the transfer yield is improved. Alternatively, the angle between the protrusion and the horizontal plane is 75° to 90°.

According to the present disclosure, preferably, the width of the protrusion is 0.1 µm to 0.5 µm, forming a mechanical concentration portion, which helps to support breakage of the support structure when the film is imprinted and transferred. Alternatively, the width of the protrusion is 0.5 µm to 2 µm, and mainly serves to support the support structure of the main body and forms a difference as compared with the width of the end portion.

In another aspect of the present disclosure, a manufacturing method of a display device is further provided, and the method includes the following:
Step 1. A semiconductor layer sequence is fabricated on a growth substrate. The main body of the semiconductor layer sequence is at least composed of a first type semiconductor layer, a second type semiconductor layer, and an active layer between the first type semiconductor layer and the second type semiconductor layer. The semiconductor layer sequence is distributed in an array;
A dielectric layer is at least fabricated on the side wall of the main body. The dielectric layer includes a side part and a horizontal part, the side part of the dielectric layer is attached to the side wall of the main body, and the upper end of the side part of the dielectric layer intersects with the horizontal part of the dielectric layer. A first electrical contact layer electrically connected to the first type semiconductor layer, and a second electrical contact layer electrically connected to the second type semiconductor layer are fabricated on the semiconductor layer sequence;
Step 2. The surface of the micro light-emitting diode is covered with a sacrificial layer by means of a coating manner to fabricate a first-platform light-emitting element;
Step 3. A substrate with an adhesive material is provided, and one side of the sacrificial layer of the first-platform light-emitting element is bonded to the substrate with the adhesive material;
Step 4. The growth substrate is peeled off, and part of the semiconductor layer sequence is removed, until the main body is fabricated, and part of the horizontal part of the dielectric layer is exposed;
Step 5. The sacrificial layer is removed, and the micro-LED is separated from the substrate and transferred to a packaging substrate by means of transfer imprinting;
In step 2 of the present disclosure, the thickness of the sacrificial layer is 0.8 µm to 2 µm, and the angle between the side wall of the main body and the horizontal plane is 70° to 100°. In the growth of coatings such as evaporation and sputtering, a periodic gap will be formed on the surface of the sacrificial layer due to the large growth rate difference between the horizontal plane and the vertical plane. In the meantime, in step 3, the adhesive material is filled into the periodic gap, and the adhesive material is disposed in the gap of the sacrificial layer to form a protrusion.

A micro light-emitting component provided by the present disclosure is made by using the above-mentioned processing and method.

The advantages effects of the present disclosure include: ensuring the yield of mass transfer of the product, and improving the reliability of the product during movement or transportation.

Other effects of the present disclosure will be described step by step in conjunction with specific embodiments.

### BRIEF DESCRIPTION OF THE DRAWINGS

The accompanying drawings are used to provide a further understanding of the present disclosure, and constitute a part of the specification, serve to explain the present disclosure together with the embodiments of the present disclosure, and do not constitute a limitation to the present disclosure. Furthermore, the figures in the drawings are descriptive summaries and are not drawn to scale.

FIGS. 1 to FIG. 6 are schematic cross-sectional structural views of a method for fabricating a micro light-emitting component according to the first embodiment of the present disclosure.

FIG. 7 is a schematic top view of the structure of a micro light-emitting component according to the second embodiment of the present disclosure.

FIG. 8 is a schematic cross-sectional structural view of a micro light-emitting component according to the third embodiment of the present disclosure.

FIG. 9 is a schematic cross-sectional structural view of a micro light-emitting component according to the fourth embodiment of the present disclosure.

FIG. 10 is a schematic cross-sectional structural view of a micro light-emitting component according to the fifth embodiment of the present disclosure.

FIG. 11 is a schematic cross-sectional structural view of a micro light-emitting component according to the sixth embodiment of the present disclosure.

FIG. 12 is a schematic cross-sectional structural view of a micro light-emitting component according to the seventh embodiment of the present disclosure.

FIG. 13 is a schematic cross-sectional structural view of a micro light-emitting component according to the eighth embodiment of the present disclosure.

### DESCRIPTION OF THE EMBODIMENTS

In order to make the purpose, technical scheme and advantage of the embodiment of the present disclosure clearer, the technical scheme in the embodiment of the present disclosure is clearly and thoroughly described below in conjunction with the accompanying drawings in the embodiment of the present disclosure. Clearly, the embodiments described below are part of the embodiments of the present disclosure, but not all of the embodiments. Based on the embodiments of the present disclosure, all other embodiments obtained by those skilled in the art without creative efforts shall fall within the protection scope of the present disclosure.

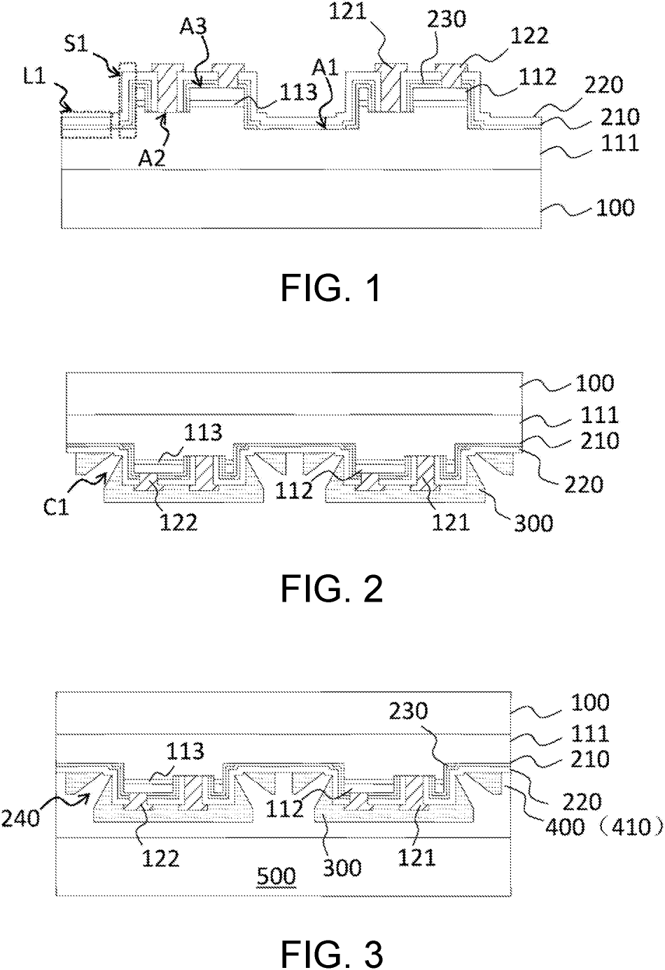

Referring to FIG. 1 to FIG. 7, in the first embodiment of the present disclosure, a manufacturing method of a micro light-emitting component is provided, and the method includes the following:

Referring to FIG. 1, in step 1, a growth substrate 100 is provided, and a semiconductor layer sequence is fabricated on the growth substrate 100. The semiconductor layer sequence includes: a first semiconductor layer 111, a second semiconductor layer 112, and an active layer 113 located therebetween. By exposing the first semiconductor layer 111 through removing the second semiconductor layer 112 and the active layer 113 in a local pattern, an epitaxy pattern including a first platform A1 composed of the first semiconductor layer 111 for extending the semiconductor layer sequence, a second platform A2 for forming electrode windows, and a platform A3 composed of a second semiconductor layer 112 is fabricated on the semiconductor layer sequence. The semiconductor layer sequence is distributed in an array. A dielectric layer covers the semiconductor layer sequence. The dielectric layer includes a first dielectric layer 210 and a second dielectric layer 220 in order. The dielectric layer may also be a single dielectric material. The thickness of the second dielectric layer 220 is variable. The thickness of the second dielectric layer 220 at least partially away from the main body is smaller than the thickness of the second dielectric layer 220 below the main body. In this embodiment, a third dielectric layer 230 may be disposed between the first dielectric layer 210 and the semiconductor layer sequence, and the first dielectric layer 210 covers the side surface of the third dielectric layer 230. The dielectric layer includes a side part S1 and a horizontal part L1, the side part of the dielectric layer is attached to the side wall of the main body, and one end of the side part of the dielectric layer intersects with the horizontal part of the dielectric layer.

On the first platform A1 and the third platform A3, the first dielectric layer 210, the second dielectric layer 220 and the third dielectric layer 230 have openings. The first electrode 121 is fabricated on the opening of the second platform A2, and the second electrode 122 is fabricated on the opening of third platform A3, and the first wafer is formed through the above process.

Referring to FIG. 2, in step 2, the sacrificial layer 300 covers the surface of the first wafer, and the sacrificial layer 300 is a removable metal material. Specifically, the sacrificial layer 300 sequentially covers the surface of the second dielectric layer 220. The above process is performed to fabricate the second wafer. A thin-film sacrificial layer 300 is provided. The thickness of the sacrificial layer 300 is 0.8 µm to 2 µm. The angle between the side wall of the main body and the horizontal plane is 70° to 100°. In this embodiment, the side wall of the main body is substantially at the same inclination angle as the side part S1, and the horizontal part L1 is close to or equal to the horizontal plane. Since the sacrificial layer 300 is grown by means of evaporation or sputtering, the growth rates of the plane and the side surface are inconsistent. Take the vertical surface as an example, the growth rate of the film on the vertical surface is much lower than the growth rate of the plane film, and a periodic gap C1 will be formed on the surface of the sacrificial layer 300.

Referring to FIG. 3, in step 3, a substrate 500 with an adhesive material 400 is provided, and one side of the sacrificial layer 300 of the first-stage light-emitting element is bonded to the substrate 500 with the adhesive material 400. The adhesive material 400 is filled into the periodic gap C1, the adhesive material 400 is disposed in the gap C1 of the sacrificial layer 300 to form the protrusion 240.

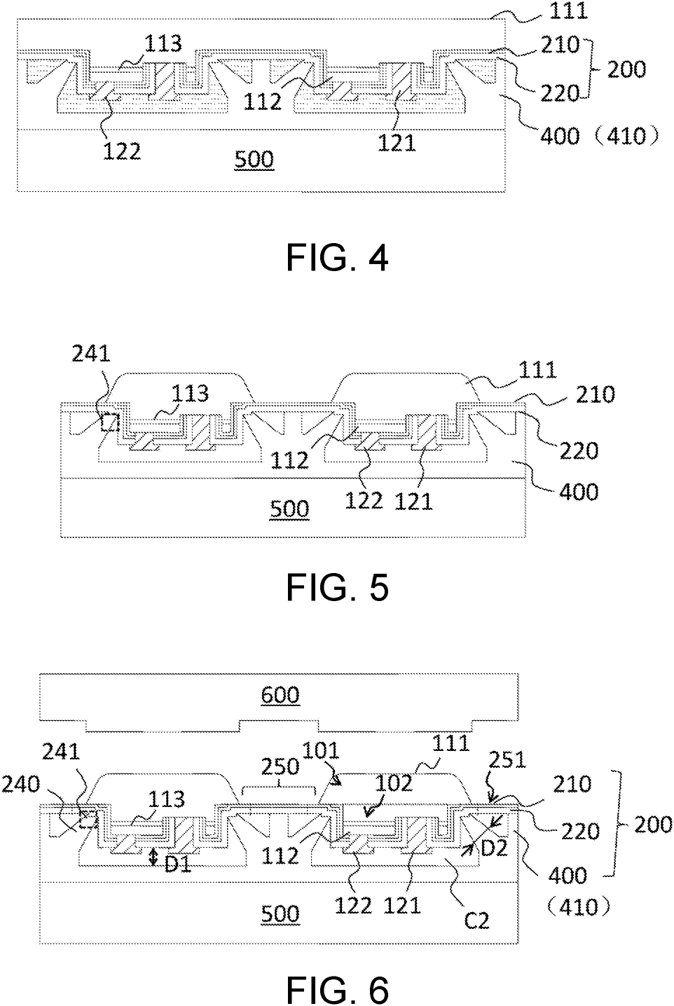

Referring to FIG. 4 to FIG. 5, in step 4, the growth substrate 100 is peeled off; and part of the semiconductor layer sequence is removed. In this embodiment, part of the first semiconductor layer 111 is removed, the first dielectric layer 210 is exposed, thus forming a plurality of separate main bodies of the micro-LED. In some embodiments, the exposed first dielectric layer 210 is removed. In an embodiment, the first dielectric layer 210 may also be further removed by over-etching, that is, the first dielectric layer 210 extends along the outer edge of the main body, and the distance between the first dielectric layer 210 and the outer edge of the main body is not greater than 0.2 µm.

In step 5, the sacrificial layer 300 is removed to form the support structure 200 including the second dielectric layer 220. In this embodiment, the support structure 200 is at least composed of the anchor 410, the first dielectric layer 210 and the second dielectric layer 220. The micro-LEDs are connected to the substrate 500 through the support structure 200.

Referring to FIG. 6, the micro-LEDs are mass-transferred by lamination imprinting 600. Since the first dielectric layer 210 is shorter than the second dielectric layer 220, the support structure 200 is fractured at the end surface of the first dielectric layer 210 near the edge of the main body during the imprinting process. The dashed line in FIG. 6 shows the pre-fractured surface, so as to reduce the residue of the support structure 200 on the micro-LED as much as possible.

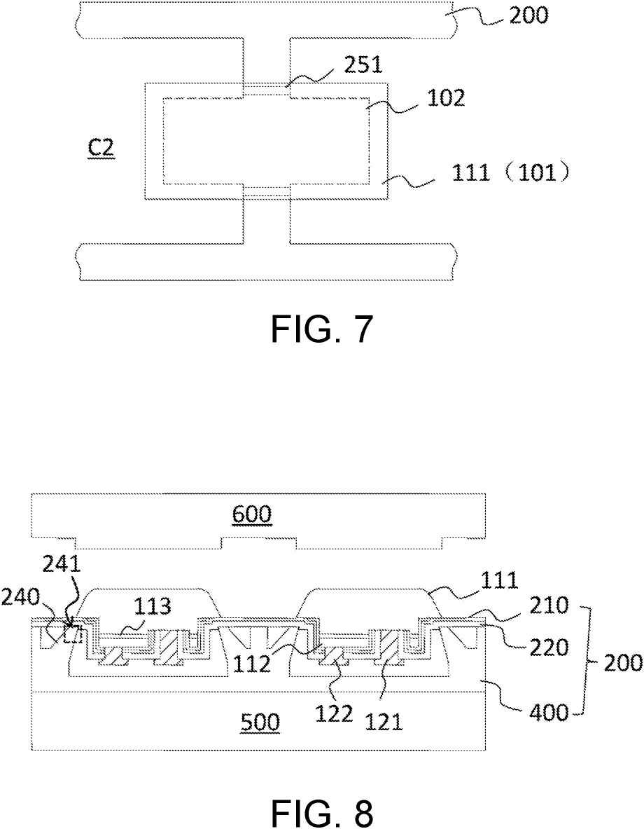

Further refer to FIG. 6 and FIG. 7 again, in a second embodiment of the present disclosure, a micro light-emitting component is provided, including: a substrate 500, a main body having a semiconductor layer sequence, a support structure 200, and the support structure 200 fixes the main body on the substrate 500. There is a cavity C2 between the main body and the substrate 500. The support structure 200 includes a protrusion 240, and the protrusion 240 points at the support structure 200 from below the support structure 200. The protrusion 240 has at least one end portion 241. The distance between the end portion 241 and the support structure 200 is 0 µm to 1 µm, and the distance between the end portion 241 and the support structure 200 is 0 µm, and the two are in direct contact. The protrusion 240 extends from the fixing anchor 410 toward the bridge arm. The protrusion 240 includes a dielectric material, an adhesive material or metal. In this embodiment, the adhesive material is, for example, epoxy resin, polyimide, benzocyclobutene or silica gel. In a preferred solution, the material of the protrusion 240 is the same as that of the anchor 410, and is preferably silica gel. The protrusion 240 has a support end surface. In this embodiment, the angle between the protrusion 240 and the horizontal plane is 45° to 75°, and the width D2 of the protrusion 240 is 0.5 µm to 2 µm.

The semiconductor layer sequence includes a first semiconductor layer 111, a second semiconductor layer 112 and an active layer 113 located therebetween. In this embodiment, the material of the semiconductor layer sequence is gallium nitride or gallium arsenide system.

In this embodiment, in the cross-sectional view, the area of the top surface of the first semiconductor layer 111 is larger than the area of the top surface of the second semiconductor layer 112, and the area of the top surface of the first semiconductor layer 111 is larger than that of the active layer 113. The centres of the first semiconductor layer 111, the second semiconductor layer 112, and the active layer 113 are substantially coincident on the vertical projection plane. The semiconductor layer sequence includes a first portion 101 away from the substrate 500 and a second portion 102 close to the substrate 500. The projection of the first portion 101 on the horizontal plane is greater than the projection of the second portion 102 on the horizontal plane. The first portion 101 is disposed on the second portion 102, the support structure 200 extends from below the first portion 101 and from the side part of the second portion 102 to the substrate 300. In this embodiment, the first portion 101 is an N-type semiconductor layer, and the second portion 102 is an N-type semiconductor layer, a P-type semiconductor layer and an active layer formed by quantum wells and located therebetween.

One end of the support structure 200 is directly or indirectly connected to the main body of the micro-LED, and one end is directly or indirectly connected to the substrate 500. The support structure 200 at least includes a first dielectric layer 210 and a second dielectric layer 220, defines one side surface of the first semiconductor layer 111 of the main body as the first surface, and defines one side surface of the second semiconductor layer 112 of the main body as the second surface. The first dielectric layer 210 is connected to the semiconductor layer sequence/the second surface of the main body. The first surface is opposite to the second surface, or directly covers the semiconductor layer sequence/the second surface of the main body, and the second dielectric layer 220 covers the surface of the first dielectric layer 210. The first dielectric layer 210 at least is partially disposed between the second dielectric layer 220 and the semiconductor layer sequence. The material of the first dielectric layer 210 is different from the material of the second dielectric layer 220. Comparing two different materials with the same material, the stress regulation of the single-layer material is easily limited by the stress and control conditions of the film-forming apparatus. The present disclosure uses the two dielectric materials to easily balance the residual stress generated in the process. In other words, the opposite stress that produces greater elasticity is generated.

The semiconductor layer sequence is the main body, and the angle between the side wall of the main body and the horizontal plane is 70° to 100°. The distance between the end portion 241 and the side part S1 as well as the side wall is 0.5 µm to 1 µm.

There is a cavity C2 on the main body formed by the semiconductor layer sequence and the upper surface of the substrate 500. Considering that the bottom surface of the main body is also provided with the first electrode 121 electrically connected to the first semiconductor layer 111, and the second electrode 122 electrically connected to the second semiconductor layer 112, the spacing D1 of the reserved cavity C2 is 0.5 µm to 3 µm. In this embodiment, the spacing D1 of the cavity C2 is the distance from the second dielectric layer 220 to the upper surface of the substrate 500, and the cavity C2 is a displacement space reserved for downward movement of the micro-LEDs in the imprinting process of transferring the core particles, so as to prevent the core particles from being damaged by the substrate 500 or the patterns thereon.

In this embodiment, the support structure 200 constitutes a bridge arm 250, the micro-LEDs are suspended from the substrate 500 through the bridge arm 250, and the bridge arm 250 and the substrate 500 form a gap C1.

The thickness of the second dielectric layer 220 is 1.5 times to 10 times the thickness of the first dielectric layer 210. First, the first dielectric layer 210 with thinner thickness is mainly adopted to eliminate the stress in the manufacturing process, so as to prevent the support structure 200 from breaking due to stress release during the bonding process. The second dielectric layer 220 is mainly adopted to provide a bridge between the core particles and the substrate 500 during transfer. The thickness of the second dielectric layer 220 is significantly greater than the thickness of the first dielectric layer 210, and in the meantime, the difficulty of stress regulation of the support structure 200 is reduced by utilizing the difference in material and film-forming stress between the two.

In this embodiment, preferably each of the first dielectric layer 210 and the second dielectric layer 220 are provided in one layer in the support structure 200. The material of the first dielectric layer 210 is silicon oxide, the first dielectric layer 210 at least includes a material of a negative stress direction, and the material of the second dielectric layer 220 at least includes a material of a positive stress direction. Moreover, the absolute value of the unit positive stress of the second dielectric layer 220 is smaller than the absolute value of the unit negative stress of the first dielectric layer 210, which facilitates to adjust the overall stress condition. The first dielectric layer 210 is connected to the semiconductor layer sequence of the main body, and the material of the second dielectric layer 220 is silicon nitride. In this embodiment, the stress of silicon oxide is 0 MPa to -200 MPa, and the stress of silicon nitride is -100 MPa to +100 MPa.

The first dielectric layer 210 and/or the second dielectric layer 220 extend downward along the side surface of the main body of the micro-LEDs, and substantially cover the bottom surface of the main body. The first electrode 121 and the second electrode 122 are exposed from the first dielectric layer 210 and/or the second dielectric layer 220 on the bottom surface.

In this embodiment, the first dielectric layer 210 and/or the second dielectric layer 220 may be located on both sides of the main body, or may be located on one side of the main body.

In the present embodiment, the support structure 200 includes an adhesive material, an inorganic medium or a metal as the fixing anchor 410, preferably the adhesive material is adopted as the fixing anchor 410, and the fixing anchor 410 is directly arranged on the substrate. One end of the first dielectric layer 210 and/or the second dielectric layer 220 is disposed on the fixing anchor 410, and the first dielectric layer 210 and/or the second dielectric layer 220 are indirectly connected to the substrate 500 through the fixing anchor 410. In some embodiments, the fixing anchor 410 is provided on both sides of the main body. The support structure 200 has a bridge arm 250 whose surface is entirely exposed or whose upper surface is exposed. The bridge arm 250 has a suspended portion 251. The protrusion 240 extends from the substrate to the suspended portion 251 of the support structure 200, and the angle between the suspended portion 251 and the horizontal plane is -10° to 10°. The bridge arm 250 is composed of the first dielectric layer 210 and the second dielectric layer 220, and the thickness of the bridge arm 250 is 0.2 µm to 1 µm.

Referring to FIG. 8, in the third embodiment of the present disclosure, the difference between the third embodiment and the second embodiment is that the main body of each semiconductor layer sequence is correspondingly provided with a plurality of pairs of end portions 241 symmetrically arranged relative to the main body. The distance between the end portion 241 and the side part S1 and the side wall is 1 µm to 3 µm, and the distance between the pair of end portions 241 is increased. In the thin bridge arm design with a bridge arm thickness of 0.2 µm to 1 µm, the device reliability is improved.

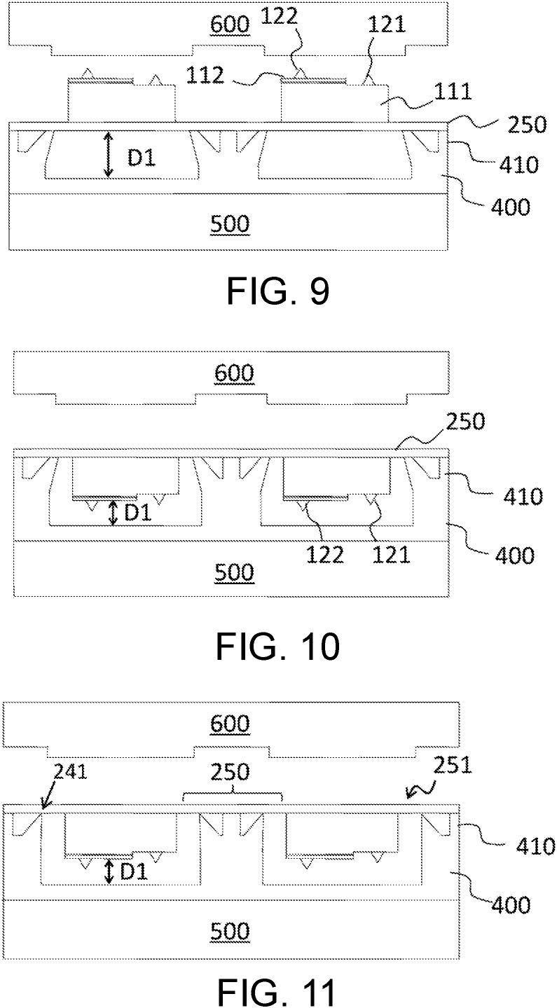

Referring to FIG. 9, in the fourth embodiment of the present disclosure, the difference between the fourth embodiment and the second and third embodiments is that the main body is designed on one side of the bridge arm 250 away from the substrate 500, the first electrode 121 and the second electrode 122 are disposed on the same side, and disposed on one side of the main body away from the cavity C2. More space is reserved for disposing the protrusion 240 to avoid the arrangement of the protrusion 240 being too crowded, resulting in abnormal chip. The spacing D1 of the reserved cavity C2 is 3 µm to 5 µm, which makes it easier to use the protrusion 240 to control the breaking point of the support structure 200 and improve the transfer yield.

Referring to FIG. 10, in the fifth embodiment of the present disclosure, the difference between the fifth embodiment and the fourth embodiment is that the main body is disposed on one side of the bridge arm 250 close to the substrate 500, and the first electrode 121 and the second electrode 122 are disposed on the same side, and disposed on one side of the main body close to the cavity C2.

Referring to FIG. 11, in the sixth embodiment of the present disclosure, the difference between the sixth embodiment and the fifth embodiment is that the support structure 200 has a bridge arm 250 whose surface is entirely exposed or whose upper surface is exposed. The bridge arm 250 has a suspended portion 251. The protrusion 240 extends from the substrate to the suspended portion 251 of the support structure 200, and the end portion 241 of the protrusion 240 is ridge-shaped or pointed. The minimum width of the end portion is 0.01 µm to 1 µm.

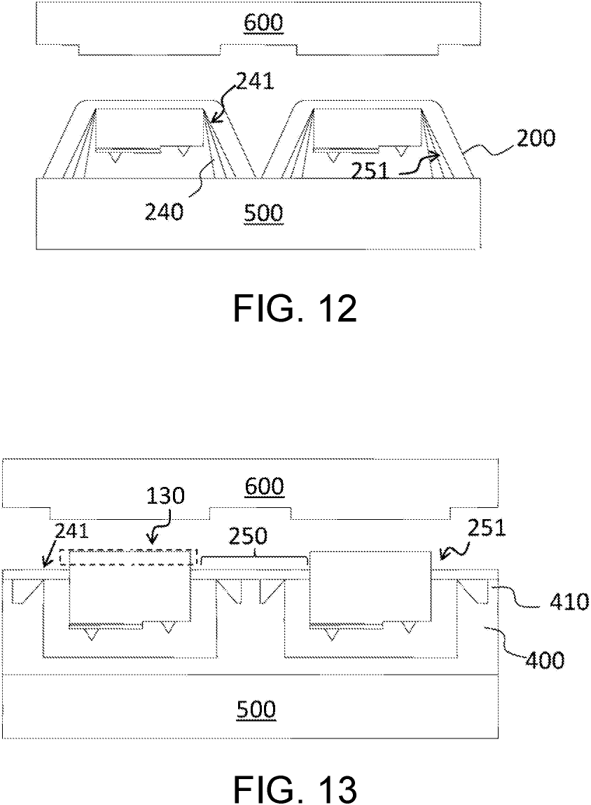

Referring to FIG. 12, in the seventh embodiment of the present disclosure, the difference between the seventh embodiment and the sixth embodiment is that the support structure 200 is a bridge structure, which is bridged upward from the substrate 500 to the upper surface of the main body. The supporting force of the main body is provided by the adhesion force of the support structure 200 to the upper surface of the main body or the clamping force to the side surface of the main body. The protrusion 240 extends from the substrate to the suspended portion 251 of the support structure 200, and the end portion 241 of the protrusion 240 is ridge-shaped or pointed. The minimum width of the end portion is 0.01 µm to 1 µm, and the end portion 241 points at the suspended portion 251.

Referring to FIG. 13, in the eighth embodiment of the present disclosure, the difference between the eighth embodiment and the sixth embodiment is that the eighth embodiment includes several micro-LEDs, a substrate 500 having a cavity C2 for accommodating the micro-LEDs, and a support structure 200 for connecting the micro-LEDs and the substrate 500. The bridge arm 250 of the support structure 200 is located on the upper surface of the micro-LEDs, and the number of the bridge arms 250 is greater than or equal to 1. The upper surface of the main body is provided with a convex 130 higher than the bridge arm 250. The main body is located between the convex 130 and the cavity C2, or the upper surface of the bridge arm 250 connected with the micro-LED is provided with the convex 130, and the micro-LED is located between the convex 130 and the cavity C2. During mass transfer of the micro light-emitting components, patterned lamination imprinting is adopted for mass transfer.

In the ninth embodiment of the present disclosure, a display device is provided, which adopts the micro light-emitting components in the above-mentioned embodiments.

The above are only the preferred embodiments of the disclosure. It should be pointed out that for those of ordinary skill in the art, some improvements and replacements can also be made without departing from the technical principle of the disclosure, and these improvements and replacement should also be regarded as the protection scope of this disclosure.

What is claimed is:

1. A micro light-emitting component, comprising: a substrate, a main body having a semiconductor layer sequence, and a support structure, wherein the support structure fixes the main body on the substrate, and a cavity is between the main body and the substrate, the support structure comprises a protrusion pointing at the support structure from below the support structure, the protrusion has at least one end portion, a distance between the end portion and the support structure is 0 µm to 1 µm.

2. The micro light-emitting component according to claim 1, wherein the support structure at least comprises a first dielectric layer and/or a second dielectric layer, a material of the first dielectric layer comprises silicon oxide, and a material of the second dielectric layer comprises silicon nitride.

3. The micro light-emitting component according to claim 1, wherein the support structure at least comprises a first dielectric layer and a second dielectric layer, a material of the first dielectric layer is different from a material of the second dielectric layer, the first dielectric layer is located between the second dielectric layer and the semiconductor layer sequence, and the second dielectric layer is configured to connect the support structure and the main body, the first dielectric layer is located on a surface of the second dielectric layer; wherein a thickness of the second dielectric layer is greater than a thickness of the first dielectric layer.

4. The micro light-emitting component according to claim 3, wherein the thickness of the second dielectric layer is 1.5 times to 10 times the thickness of the first dielectric layer, the second dielectric layer is located on the main body, and the first dielectric layer at least partially covers an outer surface of the second dielectric layer.

5. The micro light-emitting component according to claim 3, wherein the first dielectric layer is located on the main body, and the second dielectric layer at least partially covers an inner surface of the first dielectric layer.

6. The micro light-emitting component according to claim 3, wherein the material of the first dielectric layer is silicon oxide, the first dielectric layer is connected to the semiconductor layer sequence of the main body, the material of the second dielectric layer is silicon nitride, and the thickness of the first dielectric layer is 0.1 µm to 0.5 µm; the thickness of the second dielectric layer is 0.15 µm to 0.3 µm, 0.3 µm to 0.8 µm, or 0.8 µm to 2 µm, and widths of the first dielectric layer and the second dielectric layer are 1 µm to 20 µm.

7. The micro light-emitting component according to claim 3, wherein the semiconductor layer sequence is made of a gallium nitride-based material, and the semiconductor layer sequence is at least composed of a first semiconductor layer, an active layer and a second semiconductor layer, the semiconductor layer sequence comprises a first portion away from the substrate and a second portion close to the substrate, and a projection of the first portion on a horizontal plane is larger than a projection of the second portion on the horizontal plane, the second portion at least comprises the active layer and the second semiconductor layer, and the first dielectric layer and/or the second dielectric layer is/are disposed on a side wall of the second portion.

8. The micro light-emitting component according to claim 3, wherein the support structure comprises a fixing anchor and a bridge arm, the bridge arm extends from the fixing anchor toward the main body, and a material of the fixing anchor comprises an adhesive material, an inorganic medium or metal, wherein the adhesive material comprises epoxy resin, polyimide, benzocyclobutene or silica gel, and the first dielectric layer and/or the second dielectric layer are connected to the substrate through the fixing anchor.

9. The micro light-emitting component according to claim 3, wherein in the support structure, the first dielectric layer and the second dielectric layer are each a single-layer structure, the thickness of the second dielectric layer is variable, and a thickness of the second dielectric layer at least partially away from the main body is smaller than a thickness of the second dielectric layer below the main body.

10. The micro light-emitting component according to claim 3, wherein the first dielectric layer at least comprises a material of a negative stress direction, and the material of the second dielectric layer at least comprises a material of a positive stress direction.

11. The micro light-emitting component according to claim 1, wherein the protrusion comprises a dielectric material, an adhesive material or metal.

12. The micro light-emitting component according to claim 1, wherein the protrusion comprises epoxy resin, polyimide, benzocyclobutene, or silicone.

13. The micro light-emitting component according to claim 8, wherein the protrusion extends from the fixing anchor toward the bridge arm.

14. The micro light-emitting component according to claim 1, wherein the end portion of the protrusion has a ridge shape or a pointed shape, a width of the end portion is not greater than that of other regions of the protrusion, and an elastic modulus of a material of the protrusion is 0.5 GPa to 2 GPa.

15. The micro light-emitting component according to claim 1, wherein the support structure has a suspended portion whose surface is completely exposed or whose upper surface is exposed, the protrusion extends from the substrate toward the suspended portion of the support structure, and an angle between the suspended portion and a horizontal plane is -10° to 10°.

16. The micro light-emitting component according to claim 1, wherein the support structure comprises a bridge arm, and a thickness of the bridge arm is 0.2 µm to 1 µm, or 1 µm to 2 µm.

17. The micro light-emitting component according to claim 1, wherein the semiconductor layer sequence is the main body, an angle between a side wall of the main body and a horizontal plane is 70° to 100°, and a distance between the end portion and the side wall is 0.5 µm to 1 µm.

18. The micro light-emitting component according to claim 1, wherein an angle between the protrusion and a horizontal plane is 45° to 75°, or 75° to 90°.

19. The micro light-emitting component according to claim 1, wherein a width of the protrusion is 0.1 µm to 0.5 µm, or 0.5 µm to 2 µm.

20. A manufacturing method of a micro light-emitting component, comprising:
step 1. fabricating a semiconductor layer sequence on a growth substrate, wherein a main body composed of the semiconductor layer sequence is at least composed of a first type semiconductor layer, a second type semiconductor layer, and an active layer between the first type semiconductor layer and the second type semiconductor layer, the semiconductor layer sequence is distributed in an array; fabricating a dielectric layer at least on a side wall of the main body, wherein the dielectric layer comprises a side part and a horizontal part, the side part of the dielectric layer is attached to the side wall of the main body, and an upper end of the side part of the dielectric layer intersects with the horizontal part of the dielectric layer; fabricating a first electrical contact layer electrically connected to the first type semiconductor layer, and a second electrical contact layer electrically connected to the second type semiconductor layer on the semiconductor layer sequence;
step 2. covering a surface of a micro-LED (light-emitting diode) with a sacrificial layer by means of a coating manner to fabricate a first-stage light-emitting element;
step 3. providing a substrate with an adhesive material, and bonding one side of the sacrificial layer of the first-stage light-emitting element to the substrate with the adhesive material;
step 4. peeling off the growth substrate, and removing a part of the semiconductor layer sequence, until the main body is fabricated, and a part of the horizontal part of the dielectric layer is exposed;
step 5. removing the sacrificial layer, and separating the micro-LED from the substrate and transferring the micro-LED to a packaging substrate by means of transfer imprinting; wherein in step 2, a thickness of the sacrificial layer is 0.8 µm to 2 µm, and an angle between the side wall of the main body and a horizontal plane is 70° to 100°, a periodic gap is formed on a surface of the sacrificial layer, in step 3, the adhesive material is filled into the periodic gap of the sacrificial layer to form a protrusion.

21. A display device, manufactured by the manufacturing method as claimed in claim 20.
